(19) United States
(12) Patent Application Publication
(10) Pub. No.: US 2025/0008700 A1
(43) Pub. Date: Jan. 2, 2025

(54) COOLING SYSTEM FOR ELECTRONIC COMPONENT RACKS

(71) Applicant: JJ COOLING INNOVATION SÀRL, Lausanne (CH)

(72) Inventors: John R. Thome, Pully (CH); Jackson B. Marcinichen, Lausanne (CH)

(21) Appl. No.: 18/710,077

(22) PCT Filed: Nov. 15, 2022
(86) PCT No.: PCT/EP2022/081895

§ 371 Date: May 14, 2024

(30) Foreign Application Priority Data
Nov. 16, 2021 (EP) 21208623.5

(51) Int. Cl. H05K 7/20

(52) U.S. Cl. CPC H05K 7/20809; H05K 7/20309; H05K 7/20318; H05K 7/20336

(57) ABSTRACT

Cooling system for a multi-unit electronic apparatus stack (1) comprising a plurality of stacked electronic units (3), the cooling system comprising a plurality of unit cooling systems (6) incorporated in, on or between each electronic unit, each unit cooling system (6) comprising one or more fluid flow circuits (13) configured as: —a pulsating heat pipe (PHP) including a pipe (34) having one or more channels (36) therein containing a coolant fluid, the pipe (34) extending between a condenser end (16) and an evaporator end (15), or —a thermosyphon (LTS) cooling system comprising pipes (14a, 14b) extending between a condenser end (16) and an evaporator end (15); the cooling system (2) further comprising a stack cooling system (4) comprising a principal condenser (12) and a fluid flow circuit (8) including a downcomer (8a) and a riser (8b) configured as a loop thermosyphon (LTS) cooling system, the riser comprising a riser pipe (24) extending vertically across a plurality of stacked electronic units (3), each of the unit cooling systems (6) comprising a thermal interface coupling (16) thermally coupled to the riser pipe (24), the fluid flow circuits (13) of the unit cooling systems being independent from the fluid flow circuit (8) of the stack cooling system (4).

The present invention relates to a system for cooling electronic units in a multi-unit rack. In particular the present invention is directed to the cooling of computer servers. The field of the invention however extends more generally to the cooling of electronic units of other types that are stacked.

High power datacenter servers, power electronics modules and telecom data transmission equipment are commonly installed in electronics racks with a requirement of high density of heat dissipation per unit volume in the rack. Thus, these racks need to be effectively and efficiently cooled to thermally manage the operating temperatures of the installed electronics to stay within their allowable working range. The technical challenge is to remove a large quantity of heat from a confined/compact volume using as little energy to drive the cooling system as possible.

Current cooling technologies are available principally in four forms: (i) air-cooling with fans blowing air over heat sinks with or without embedded heat pipes, (ii) water-cooling with pump(s) driving the water through heat sinks, (iii) immersion cooling in which the entire rack is emerged in a liquid cooled bath of dielectric liquid, and (iv) individual thermosyphon heat sinks cooled by air with fans placed in each server.

Air-cooling is an expensive electrical energy consumer and cannot handle the very high heat densities of the new powerful electronics as the air flow rate and fan noise become prohibitive. Water-cooling is a high risk if any leak or drip occurs into the electronics during operation or servicing. Immersion cooling requires twice as much floor space to install the tall rack horizontally and creates additional maintenance issues. Individual air-cooled thermosyphons, which are a mini-thermosyphon for each individual electronic component cooled by air flow within the server, extend the range of air-cooling to higher heat loads than (i) but do not handle the high heat loads in 1U servers (1.75 inch or 44.4 mm height) commonly used in densely packed racks and in any case still have the air flow rate and fan noise problems.

Cooling stacked computer servers with thermosyphons are described for instance in US 20190107333, US 20200015387, US 20200113083, and WO 2007102978. The advantage of thermosyphons is their ability to transfer large amounts of heat in a compact configuration compared to air-cooled systems. However, in conventional systems, the coupling of the computer servers to the thermosyphon network renders the system complex and configurations with different numbers of servers or the replacement of individual units is time consuming and laborious.

In view of the foregoing, it is an object of the invention to provide a cooling system for a multi-unit stack of electronic devices that is compact with a high heat transfer capability, yet that is economical to manufacture, configure and install.

It is advantageous to provide a cooling system for a multi-unit electronic apparatus that allows easy and economical replacement of electronic units.

It is advantageous to provide a cooling system for a multi-unit electronic apparatus that is reliable and can be easily and economically adapted for different numbers of electronic units.

It is advantageous to provide a cooling system for a multi-unit electronic apparatus that can be easily and economically integrated into existing electronic units.

Various objects of the invention have been achieved by providing a cooling system according to the independent claims.

Dependent claims set out various advantageous features of embodiments of the invention.

Disclosed herein is a cooling system for a multi-unit electronic apparatus stack comprising a plurality of stacked electronic units. The cooling system comprises a plurality of unit cooling systems incorporated in, on or between each electronic unit.

According to a first aspect, each unit cooling system comprises one or more fluid flow circuits configured as:
a pulsating heat pipe (PHP) including a pipe having a plurality of channels therein arranged in a serpentine shape to form the pulsating heat pipe (PHP), the channels containing a coolant fluid, the pipe extending between a condenser end and an evaporator end,
   the cooling system further comprising a stack cooling system comprising a principal condenser and a fluid flow circuit including a downcomer and a riser configured as a loop thermosyphon (LTS) cooling system, the riser comprising a riser pipe extending vertically across a plurality of stacked electronic units, each of the unit cooling systems comprising a thermal interface coupling clamped and thermally coupled to the riser pipe, the fluid flow circuits of the unit cooling systems being independent from the fluid flow circuit of the stack cooling system.

According to a second aspect, each unit cooling system comprises one or more fluid flow circuits configured as:
a pulsating heat pipe (PHP) including a pipe having one or more channels therein containing a coolant fluid, the pipe extending between a condenser end and an evaporator end, or
a thermosyphon (LTS) cooling system comprising pipes extending between a condenser end and an evaporator end;
   the cooling system further comprising a stack cooling system comprising a principal condenser and a fluid flow circuit including a downcomer and a riser configured as a loop thermosyphon (LTS) cooling system, the riser comprising a riser pipe comprising a plurality of channels, the riser pipe having a substantially constant outer profile extending vertically across a plurality of stacked electronic units, each of the unit cooling systems comprising a thermal interface coupling configured to be releasably clamped and thermally coupled to the riser pipe, the fluid flow circuits of the unit cooling systems being independent from the fluid flow circuit of the stack cooling system

The riser and downcomer may be placed at any convenient position along any side or at any corner of the multi-unit electronic apparatus stack to allow easy access to the electronic units.

In an advantageous embodiment, the riser pipe comprises a substantially rectangular cross-section.

In an advantageous embodiment, the riser pipe comprises a single integrally formed outer wall and internal walls separating adjacent said channels of the riser pipe.

In an advantageous embodiment, the riser pipe cross-section has a length L to width W ratio L/W in a range of 30/1 to 3/1. The cross-sectional dimensions of the riser pipe may be constant or may vary along the height of the stack. For instance, to take into account the increase in volume as coolant changes phase from liquid to gas, the riser pipe may be provided with a greater cross-sectional area at the upper part compared to the lower part thereof. The increase may be stepwise and/or continuous.

In an advantageous embodiment, the riser pipe has substantially flat opposed surfaces and the thermal interface coupling comprises a flat surface for clamping against the flat surface of the riser pipe.

In variants, the riser pipe may have circular, polygonal or irregular shaped cross-sectional profiles, provided that the shape of the thermal interface coupling of the unit cooling systems is adapted thereto to ensure sufficient thermal coupling to the riser pipe.

In an advantageous embodiment, the pipe of the unit cooling system comprises a plurality of channels.

In an advantageous embodiment, the plurality of channels are arranged in a serpentine shape to form a pulsating heat pipe (PHP).

In an advantageous embodiment, the pipe of the unit cooling system comprises an evaporator end thermal interface coupling having a major surface for thermally coupling against a heat generating electronic component of the electronic unit.

In an advantageous embodiment, the pipe of the unit cooling system comprises a condenser end thermal interface coupling having a major surface for thermally coupling against a heat absorbing component of the rack cooling system.

In an advantageous embodiment, the pipe of the unit cooling system is formed of an extruded metal piece, for instance an extruded aluminum piece.

In an advantageous embodiment, the downcomer of the stack cooling system comprises a single channel pipe.

In an embodiment, the downcomer pipe may include a liquid accumulator.

In an advantageous embodiment, the principal condenser is arranged above the top of the multi-unit electronic apparatus stack.

In an advantageous embodiment, the principal condenser comprises an air-liquid heat exchanger.

In an advantageous embodiment, the principal condenser further comprises a liquid-liquid heat exchanger including channels for flow of the coolant of the stack cooling system and channels separate therefrom for flow of a cooling liquid, which may for instance come from the air-liquid heat exchanger.

In an advantageous embodiment, the channels include alternating layers of separate micro-cooling channels, the micro-cooling channels of each layer arranged in a single block for each fluid flow with respective inlet and outlet connecting openings.

In an advantageous embodiment, the micro-cooling channels have a generally rectangular shape with a height H to width W ratio H/W in a range of 1.5 to 15, preferably in a range of 2 to 5.

In an advantageous embodiment, the liquid-liquid heat exchanger is a single integrally formed 3D printed part

In an advantageous embodiment, the liquid-liquid heat exchanger is made of metal.

In an advantageous embodiment, the riser pipe comprises a constant continuous geometry extending vertically across a plurality of electronic units configured to allow clamping of plate shaped thermal interface couplings of the unit cooling system at any position along the riser pipe.

Further advantageous features of the invention will be apparent from the following detailed description of embodiments of the invention and the accompanying illustrations.

### BRIEF DESCRIPTION OF THE FIGURES

FIG. 1a is a schematic representation of a conventional loop thermosyphon (LTS) passive two-phase cooling system;

FIG. 1b is a schematic representation of a conventional two-phase closed loop pulsating heat pipe (PHP) cooling system;

FIG. 1c is a schematic representation of a conventional open loop two-phase pulsating heat pipe (PHP) cooling system;

FIG. 2 is a simplified schematic representation of a multi-unit electronic apparatus stack, for instance a stack of computer servers, and associated cooling systems according to an embodiment of the invention;

FIG. 2a is a simplified schematic representation of the fluid flow circuit of a loop thermosyphon unit cooling system for a single electronic unit, for instance a server with two microprocessors;

FIG. 2b is a schematic representation similar to FIG. 2a however showing a possible configuration of a pulsating heat pipe unit cooling system according to an embodiment of the invention, for instance a server with two microprocessors;

FIG. 3 is a schematic representation of a plurality of multi-unit electronic apparatus stacks and associated cooling systems according to an embodiment of the invention;

FIG. 4a is a schematic perspective view of a thermal interface coupling between a thermosyphon unit cooling system and a riser pipe of the stack cooling system according to an embodiment of the invention;

FIG. 4b is a view similar to FIG. 4a of a variant with a pulsating heat pipe unit cooling system;

FIG. 5 is a schematic cross-sectional view through a riser pipe of a fluid flow circuit of the stack cooling system, for instance of the riser pipe of FIGS. 4a and 4b, according to an embodiment of the invention;

FIG. 6 is a perspective view of a multi-channel pipe of a fluid flow circuit forming a pulsating heat pipe unit cooling system according to an embodiment of the invention;

FIGS. 6a and 6b show cross-sectional views of ends of the multi-channel pipe of FIG. 6;

FIG. 7 is a cross-sectional view of a liquid-liquid heat exchanger of a stack cooling system, according to an embodiment of the invention;

FIGS. 8a and 8b are perspective views of air-liquid heat exchanger of a stack cooling system according to embodiments of the invention;

FIG. 9a is a perspective view, sectioned and exploded, of a liquid-liquid heat exchanger (condenser) of a stack cooling system, according to another embodiment of the invention;

FIG. 9b is a schematic simplified view of channels in a liquid-liquid heat exchanger with different widths according to a variant;

FIG. 9c is a schematic simplified view of a channel with an apex end shape in a liquid-liquid heat exchanger according to a variant.

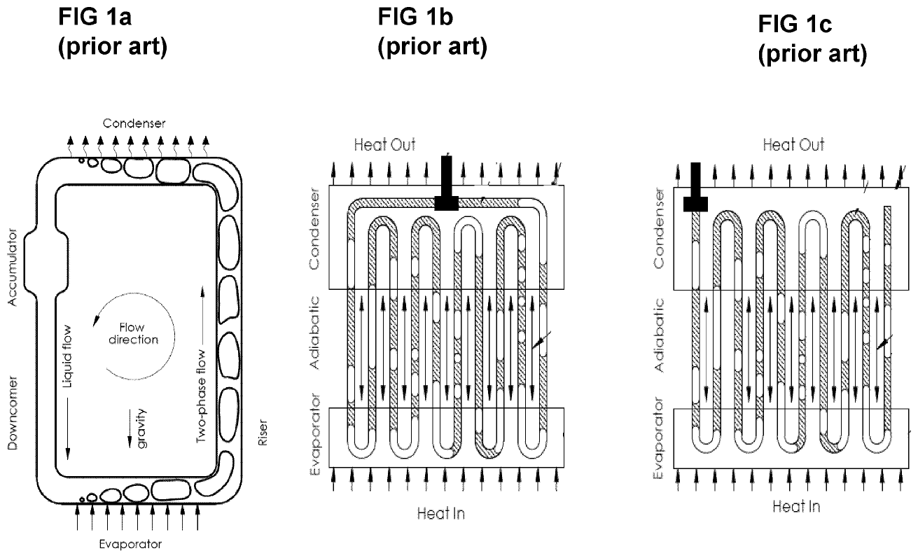

The generic conceptual channel layout and fluid flow within a per se known loop thermosyphon and pulsating heat pipe are shown in FIG. 1a (LTS), FIG. 1b (closed loop PHP) and FIG. 1c (open loop PHP).

Basically, a LTS has a gravity-driven internal coolant flow. The coolant is partially evaporated in the Evaporator removing the heat from the electronics and flows up the Riser due to buoyancy. The flow passes through the Condenser where the heat is removed to the secondary coolant (air, liquid or another two-phase flow) converting the vapor back to liquid, and finally gravity pulls the liquid down the Downcomer where the coolant reenters the Evaporator to continue the flow around the loop. It is also sometimes useful to include a liquid accumulator in the LTS loop at the exit of the condenser to manage the liquid inventory in the LTS over a wide range of operating conditions, as shown, but it is not always needed and can be removed from the loop.

A pulsating heat pipe, also known as an oscillating heat pipe, is a closed or open serpentine loop in which a fraction of the internal volume of the serpentine is filled by the liquid coolant and the remaining internal volume is filled by its vapor. The coolant boils at the evaporator end and condenses at the condenser end while the flow inside is created by instabilities from the creation and collapse of the vapor bubbles, making the flow passively oscillate from one direction to the opposite direction inside the serpentine.

All of these systems, LTS and PHP, include a filling or charging port to evacuate the loop or serpentine and to put the coolant inside them.

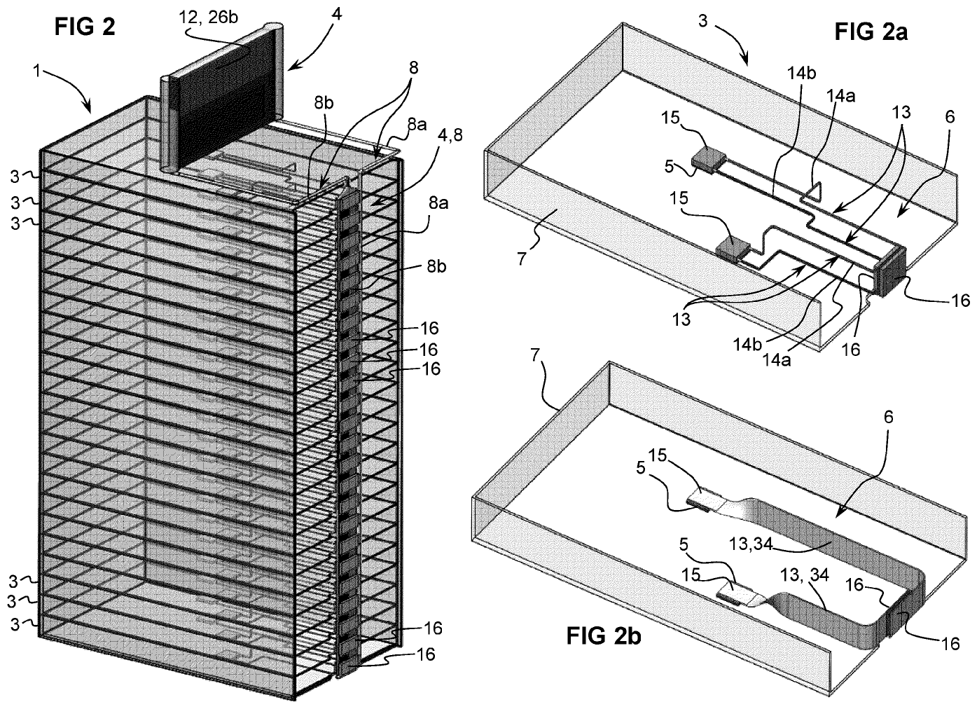

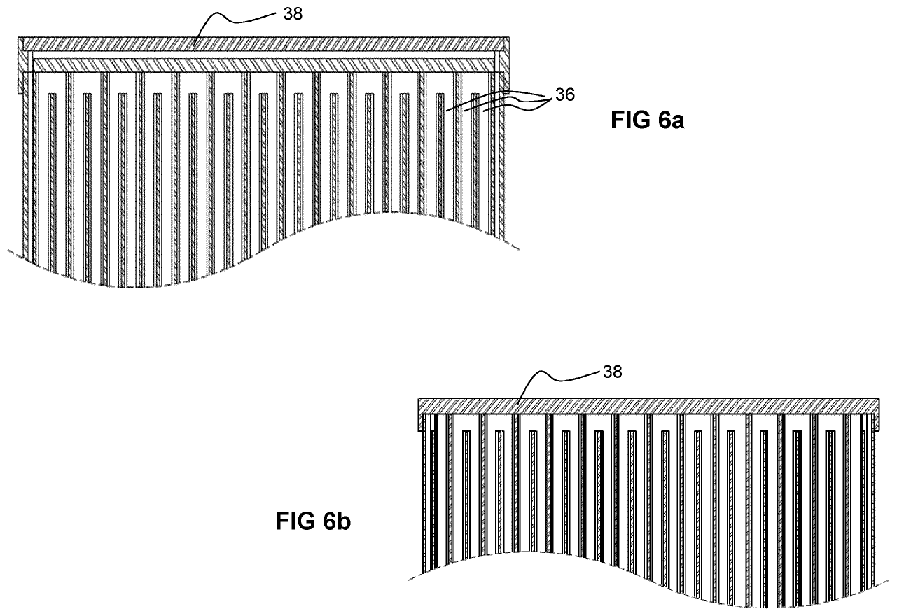

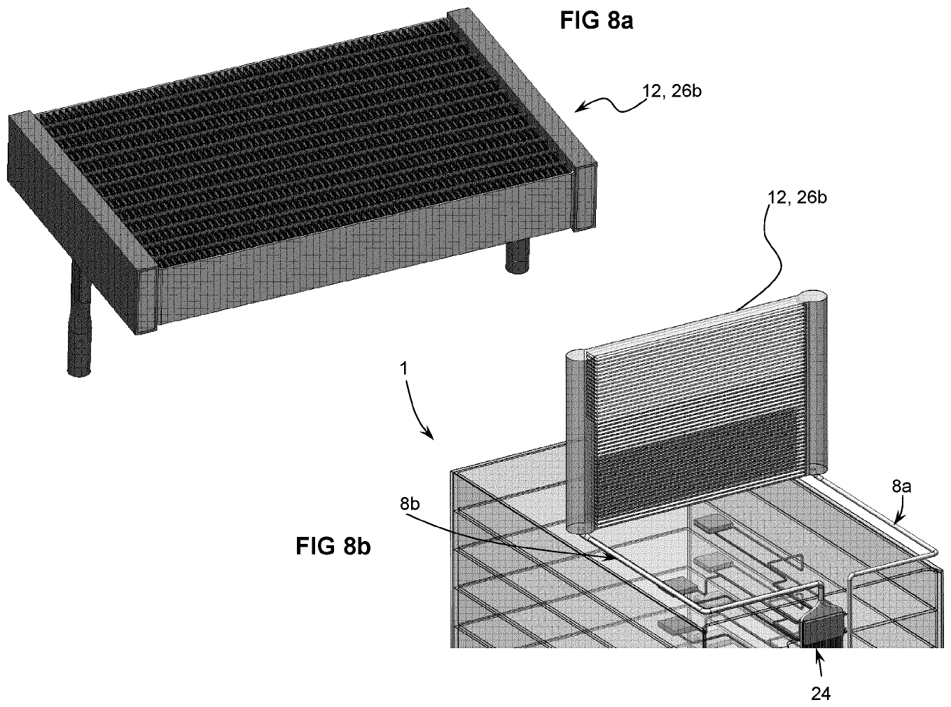

Referring to the FIGS. 2-8b, embodiments of the invention are illustrated. A multi-unit electronic apparatus stack 1 comprises a plurality of electronic units 3 grouped together, for instance arranged in at least one vertical stack. It may be noted that the multi-unit electronic apparatus stack may comprise a plurality of vertical stacks; however, for the purposes of illustrating embodiments of the invention, a single stack is illustrated and shall be described herein.

In a typical application of the invention, the electronic units may consist of computer servers, for instance computer servers of a data center. The invention however may be employed with other types of electronic units that are stacked together and require cooling.

A cooling system 2 according to embodiments of the invention is integrated with the multi-unit electronic apparatus stack.

The cooling system 2 comprises a large or principal cooling system 4 that we shall refer to herein as the stack cooling system 4, and a plurality of unit cooling systems 6 that are thermally coupled to the stack cooling system 4. The unit cooling systems 6 are incorporated in each electronic unit 3 or may be provided for a group of electronic units 3 that form a portion of the multi-unit electronic apparatus stack 1.

In the embodiments illustrated, the unit cooling system 6 comprises cooling fluid flow circuits 13, that are mounted within the housings 7 of each electronic unit, however in variants (not illustrated) the unit cooling system could be mounted as part of the housing 7 or on the outside of the electronic units 3, for instance at interfaces between two electronic units 3. In the latter case, heat sinks and heat conductive materials may bridge the heat producing electronic components 5 (for instance processors) to the housing 7 coupled to the unit cooling system.

The stack cooling system 4 comprises a principal condenser 12 and a cooling fluid flow circuit 8 configured as a thermosyphon cooling circuit. The fluid flow circuit 8 comprises a downcomer 8a and a riser 8b. The principal condenser 12 serves to cool the coolant flowing in the fluid flow circuit 8 and is preferably arranged at the top of the stack cooling system 4.

The principal condenser 12 comprises at least one heat exchanger 26a, 26b. In a preferred embodiment, the principal condenser 12 comprises an air-liquid heat exchanger 26b, and a liquid-liquid heat exchanger 26a coupled to the air-liquid heat exchanger 26b, that may be positioned above the multi-unit apparatus stack 1. The air-liquid heat exchanger 26b may be positioned at a certain distance from the stack 1 and may either be cooled by indoor air, or by environmental air (outside air), passively by natural convection, or by forced convection using fans 32, or various such heat exchanger systems being per se well known and do not need to be described further herein.

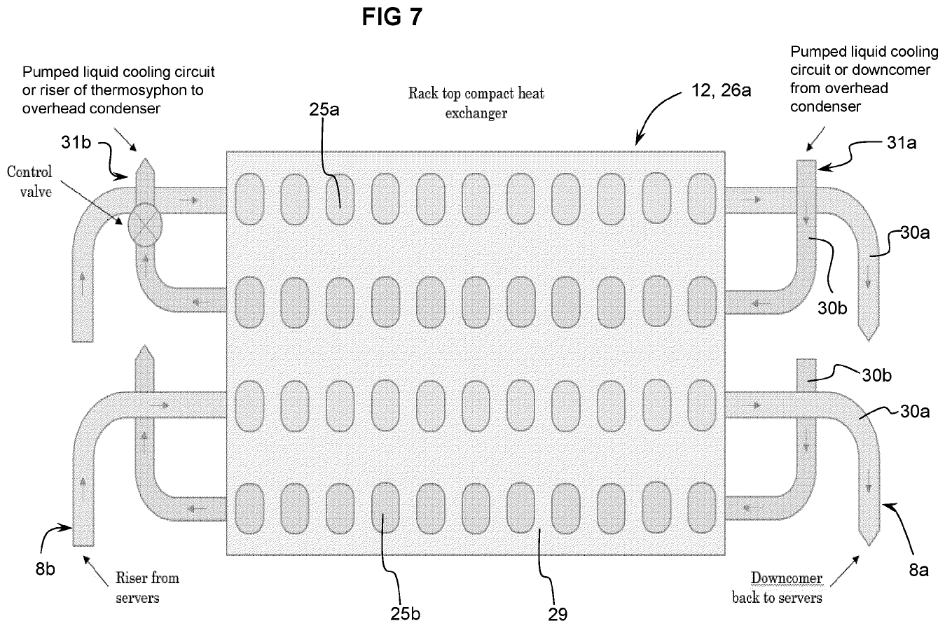

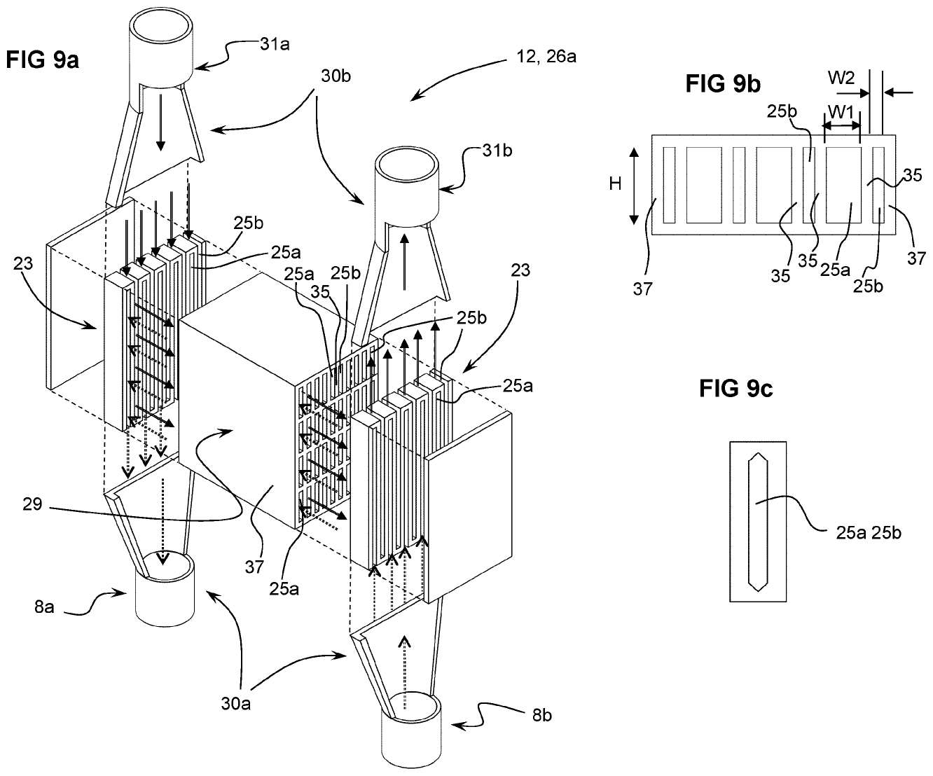

In embodiments illustrated in FIGS. 7 and 9a-9c, the liquid-liquid heat exchanger 26a comprises a liquid-liquid heat exchanger block 29 having a hot liquid circuit 30a having one or more channels 25a, for instance a serpentine channel 25a in the embodiment of FIG. 7 or a plurality of channels 25a arranged in columns as illustrated in FIG. 9a, connected to the stack cooling system fluid flow circuit 8, and a cool liquid circuit 30b, that may for instance also have a serpentine channel 25b in the embodiment of FIG. 7 or a plurality of channels 25b arranged in columns as illustrated in FIG. 9a, connected via an inlet 31a and outlet 31b to a liquid circuit 33 of a second heat exchanger, for instance a liquid-air heat exchanger 26b.

In the embodiment of FIG. 9a to 9c, the columns of channels 25a of the hot liquid circuit 30a are interweaved with the columns of channels 25b of the cool liquid circuit 30b, the channels 25a, 25b separated by thin separating walls 35. The channels advantageously have a substantially rectangular shape with the long side of the rectangles oriented in the direction of the column. Thus, heat transfer between the channels 25a of the hot liquid circuit 30a and the channels 25b of the cool liquid circuit 30b occurs through the long sides of the rectangular shaped channels. The channels 25a of the hot liquid circuit 30a may have a rectangular shape with a width W1 different to a width W2 of the rectangular channels 25b of the cool liquid circuit 30b as illustrated schematically in FIG. 9b. The entry and exit sections 23 of the liquid-liquid heat exchanger block 29 may comprise single channels that each feed into a plurality of stacked channels forming a column, the stacked channels extending through the heat exchanger block 29.

In an advantageous embodiment, the heat exchanger block 29 including the channels and inlets and outlets of both of the hot and cool liquid circuits may advantageously be made as a single integrally formed part by additive manufacturing techniques, for instance 3D printing of thermally conductive materials, preferably of 3D printable metals.

The liquid-liquid heat exchanger 26a according to embodiments of the invention, which serves as a condenser for the thermosyphon stack cooling system 4 is important for the proper thermal-hydraulic operation to achieve high thermal performance to cool the high heat loads of the electronics racks and thus is an integral part of the cooling system. A very flexible and easily modified geometry is required to handle the broad range of heat loads to be cooled by the condenser depending on the power of the electronics installed the rack and secondly on the coolant to be used for the condenser. The heat exchanger 26a requires a very low pressure drop flow path for the thermosyphon working fluid passing through it, in order to greatly reduce resistance to flow (by 50% or more) and thus increase the flow rate of the thermosyphon working fluid to attain higher electronics cooling capacities (by 20% or more) than achievable utilizing conventional tubular and plate heat exchangers on a per unit volume basis. Furthermore, this heat exchanger 26a is much smaller (e.g. by a factor of three) in volume and much lighter in weight (e.g. by a factor of three or more) compared to equivalent conventional thermal capacity conventional units to enable it to fit on top of the rack and to be safely installed on the top of rack. This very compact geometry in addition significantly reduces the amount of working fluid required to operate the thermosyphon of the stack cooling system 4 whilst its reduced weight also means the thermosyphon system is able to react faster to transient operation of the electronics and their temperatures.

Advantageous aspects of the fabrication, features and advantages of the heat exchanger block 29 compared to conventional heat exchangers include:
1. it is manufactured by a 3D printing process as one single-piece of material, not as a combination of multiple pieces that are brazed or soldered or welded or bonded together;
2. cooling channels of the heat exchanger are made in a very high density matrix of high aspect ratio rectangular (or similar) cross-section shapes coupled with very thin separating walls between the channels to achieve a very high heat transfer surface area per unit volume, a reduction in weight and a reduced overall volume;
3. it can be made from all types of metallic powders (available in aluminum, titanium, copper, stainless steel and other various metal alloys) as well in a broad range of available 3D printable plastics and polymers;
4. it allows new combinations of same or different number of channels per fluid, same or different sizes of channels for each fluid, same or different channel flow lengths per fluid, all useful to optimize heat transfer and minimize pressure drop;
5. channel sizes range from 0.1 mm to 0.5 mm width and from 0.3 mm to 5.0 mm height, creating aspect ratios H/W of height H to width W from 1.5 to 15, preferably from 2 to 5, while the wall thickness of the separating walls 35 between channels 25a, 25b and layers in core separating the fluids as low as 0.05 mm to 0.1 mm compared to values of 0.5 mm to 1.2 mm of conventional heat exchangers,
6. neighboring cooling channels of the two different fluids are situated as layers of channels one above the other and alternating the two fluids in neighboring channels in the same layer;
7. the rectangular channels may have rounded or sloped corners or inclined corners to improve printing characteristics;
8. the inlet and outlet headers for the fluids are printed as part of the one-piece unit together with the inlet and outlet fluid piping connections, such that the heat exchanger is only one integral piece of metal. This means that the outer walls 37 of the heat exchanger are locally supported internally by the channel separating walls 35, allowing their thickness to be reduced compared to conventional units. All of this reduces the total weight of the unit compared to conventional units.
9. the inlet and outlet headers notably function to exchange heat between the two fluids. In fact, the only zones of the heat exchanger not participating in heat transfer are the inlet and outlet piping connections and the outer walls.

Fabrication by the 3D printing process here includes the following processes: selective laser sintering (SLS), direct metal laser sintering (DMLS), selective laser melting (SLM), multi jet fusion (MJF), high-speed sintering (HSS) and electron beam melting (EBM). SLS is the most common for plastics, DMLS and SLM are the most common for metals. Also encompassed are numerous other variations of these 3D printing processes proposed by manufacturers for metal powders and plastics (and polymers).

In the embodiment of FIG. 9a, the condensing fluid is a vapor/liquid flow coming from the riser 8b of the thermosyphon stack cooling system and enters through one of the bottom piping connections, flows through the channels in the inlet header 23 along its length, where the fluid then flows into the stacked microchannels 25a in communication with an inlet/outlet header 23 (every other channel in each layer of channels in the core), then flows out through the inlet/outlet header 23 at the other end of the block 29 and down and out through the other piping connection connected to the downcomer pipe 8a at the bottom as a subcooled liquid flow. The cooling fluid (e.g. water/glycol+water) from the second heat exchanger 26b enters one of the top piping connections 31a, flows through the channels 25b in the inlet header 23 and along its length, where the fluid flows into the numerous microchannels 25b in communication with the inlet/outlet header 23 (every other channel in each layer of channels in the core), then flows out through the inlet/outlet header 23 on the other end and up and out through the other piping connection 31b at the top. It is possible to swap the locations of the inlet and outlet combinations to create co-current and counter-current flow of the two fluids. With simple modifications to the geometries of the inlet and outlet headers, it is possible to make one-pass flow (as illustrated) or multiple-pass flow of the fluids. It is also possible to change the shape and the placement of the inlet and outlet piping connections depending on the number of passes.

As illustrated in FIG. 9b, the width W1, W2 of the microchannels 25a, 25b can be optimized for each fluid separately, which specifically enables a very low pressure drop to be attained for the condensing fluid of the thermosyphon, which in turns increases the gravity-driven flow rate and thus enhances the thermal capacity of the thermosyphon that is cooling the electronics in the rack. In particular, the channels 25a of the hot liquid circuit may have a larger width W1 than the channels 25b of the cooling circuit. All of these benefits are made possible by the 3D printing process and the geometry proposed here.

FIG. 9c depicts a high aspect ratio microchannel of generally rectangular cross-sectional shape with an apex shape at its top or bottom, or other simple shape changes to facilitate the 3D printing process. The actual height and width of the microchannels may be optimized by a thermal-hydraulic computer simulation.

For thermosyphons, this heat exchanger may also be employed for an evaporating cooling fluid entering the top going through a boiling process while the fluid entering the bottom is going through a condensing process. For waste heat recovery from a thermosyphon, or other some other similar process, the heat exchanger is also applicable to a broader application of only single-phase liquids flowing through it, one to be heated and one to be cooled. For example, the heat exchanger may be employed for disposing of the recovered heat to a district heating line. For a thermosyphon condenser cooled by an evaporating fluid flow, the choice of the respective microchannel widths to optimize heat transfer and reduce pressure drops of both fluids is feasible here.

Furthermore, it is possible with simple geometrical changes to add an additional third or fourth fluid flow circuit within this unit for more complex applications where the third or fourth fluid are not to be mixed with the first two fluids. For example, if the thermosyphon is cooled by two different fluid circuits of water (for example one going to heat dissipation in the environment and the other going to waste heat recovery), one single heat exchanger can handle this by modifying the flow circuit to a left-side and a right-side flow through the microchannels by making simple changes in the inlet and outlet headers and adding additional inlet and outlet piping connections.

For 3D printing, one advantage is the ability to produce the printed object as light in weight as possible to reduce the material input, e.g. powder, and to reduce the printing time and thus reduce its fabrication cost. The thermosyphon condenser is one of the most expensive components of the rack thermosyphon system and thus it is useful to reduce its fabrication cost. The present heat exchanger 26a for the thermosyphon rack cooling system 4 is able to be fabricated with very thin internal walls between neighboring channels and between the layers (range of dimensions and aspect ratios were cited above). The walls and inlet and outlet piping connections of the heat exchanger are made thicker based on a mechanical stress analysis to the necessary thickness.

From a sustainability viewpoint, 3D printing requires only one material in its fabrication; that is no solders, brasing or welding materials, no metal waste or shavings, and no cleaning fluid to remove residuals of conventional fabrication processes. The powder remaining inside a 3D printed object at the end of its fabrication processes is removed and is recycled into the 3D printing of the next object).

In a variant, the principal condenser 12 may comprise only an air-liquid heat exchanger 26b, the liquid circuit thereof being connected to the riser and downcomer of the stack cooling system.

The principal condenser 12 thus receives the coolant fluid flowing in from the riser 8b and outputs the coolant fluid into the downcomer 8a that is cooled by the one or more heat exchangers 26a, 26b.

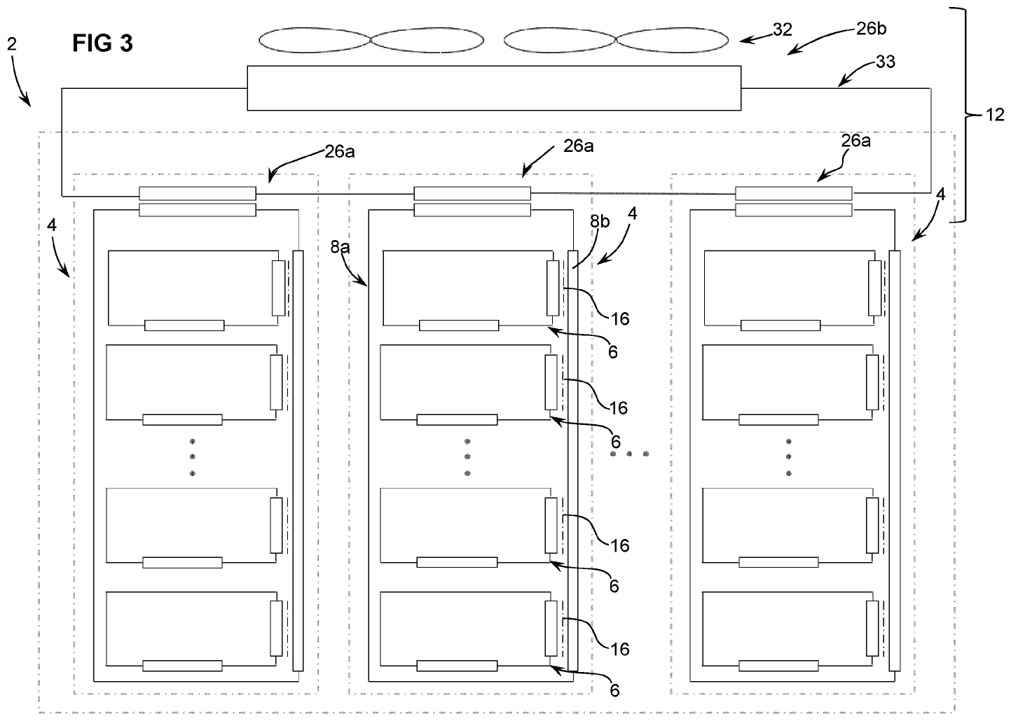

The air-liquid heat exchanger 26b, in the embodiments where it is implemented, may receive gravity-driven thermosyphon coolant rising from and returning to one or more liquid-liquid heat exchangers 26a, for instance as illustrated in FIG. 3.

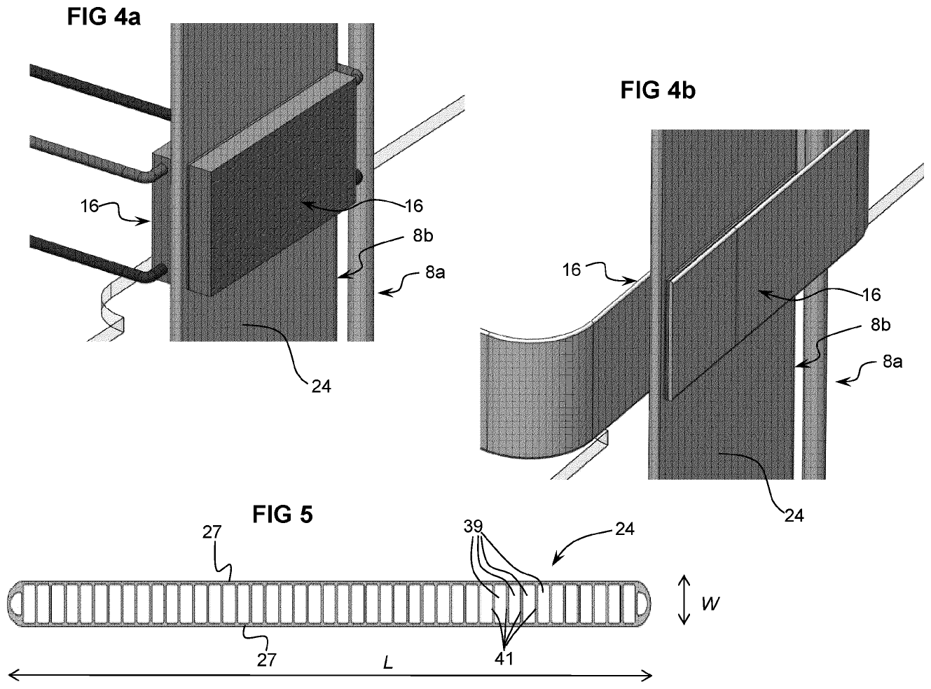

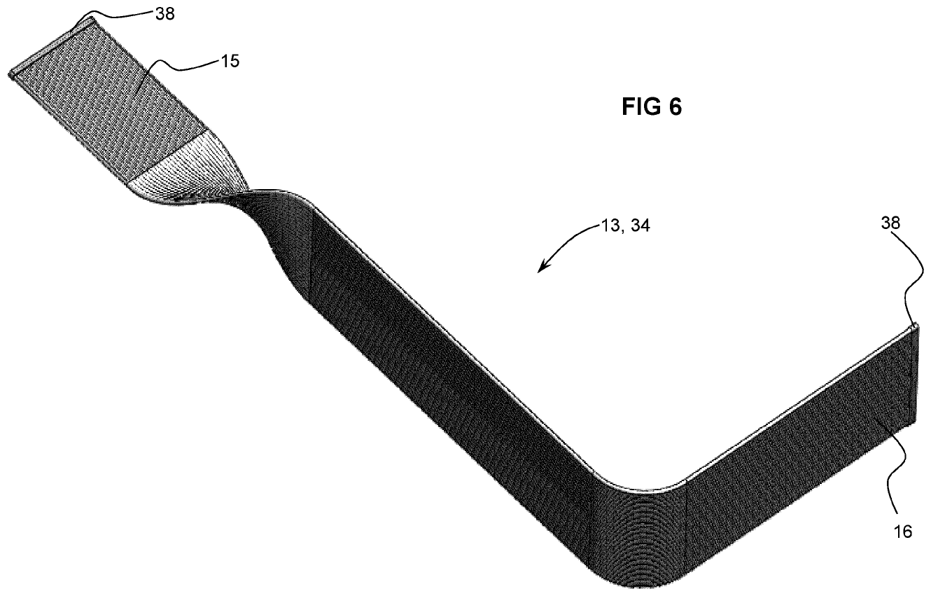

The riser 8b includes a riser pipe 24 that may have one or a plurality of channels 39 (e.g. as illustrated in FIG. 5) separated by internal walls 41 in which the coolant fluid circulates. Preferably, the riser pipe has a multi-channel configuration and a substantially constant profile across the stack of individual unit cooling, for instance a substantially flat cross-section with opposed major surfaces 27 as illustrated in FIGS. 4a, 4b, 5 in order to have a high heat exchange surface with the surface 16 of the unit cooling system 6. The outer wall 41 of the riser pipe may be a single integrally formed wall, the internal walls 41 being formed therewith and separating adjacent channels 39.

The internal walls 41 within the riser pipe 24 increase the surface area and heat exchange with the coolant fluid flowing in the riser pipe.

The riser has a plurality of evaporator sections that may simply be sections of the riser pipe against which thermal interface couplings 16 may be mounted for transferring heat from the unit cooling system 6 to the riser pipe 24.

The downcomer 8a comprises a downcomer pipe that may have the same but may have a different shape from the riser pipe and may also comprise a single channel instead of multiple channels.

In a preferred embodiment, the downcomer is not coupled thermally to individual unit cooling systems 6 and simply serves as a return line for supplying cooling fluid to the riser 8b.

The riser pipe may advantageously comprise an extruded metal construction, for instance extruded aluminum.

The riser pipe may advantageously have a substantially rectangular shape with opposed flat major outer surfaces 27 for clamping plates thereagainst that serve as a thermal interface coupling 16. The riser pipe rectangular cross-sectional profile preferably has a length L to width W ratio L/W in a range of 3/1 to 30/1 and preferably in a range of 4/1 to 20/1. These proportions provide an optimum compromise between structure rigidity, manufacturability, minimum flow resistance, and heat exchange surface area available for attaching the unit cooling system 6.

According to an aspect of the invention, the riser pipe may advantageously have a substantially linear geometry (constant profile) across a plurality of electronic units 3, for instance from the top to the bottom of the stack, such that the unit cooling systems 6 may be coupled there along at any position vertically with respect to the riser pipe without special considerations. This provides great flexibility in positioning and coupling of unit cooling systems 6 of electronic units 3 and ease of maintenance and installation.

Each unit cooling system 6 comprises a fluid flow circuit 13 in which a coolant or possibly a plurality of coolants flow configured as a LTS or PHP cooling system. For the LTS, the fluid flow circuit 13 comprises an evaporator line (or pipe) 14a that is connected as an input to a thermal interface coupling 16 thermally coupled to the riser 8b of the stack cooling system 4, and as an output to a thermal interface coupling 15 thermally coupled to a heat generating component 5 of the electronic unit 3, for instance a processor thereof. The fluid flow circuit 13 also comprises a condenser line (or pipe) 14b that is connected as an output to the thermal interface coupling 16 thermally coupled to the riser 8b of the stack cooling system 4, and that is connected as an input to the thermal interface coupling 15 thermally coupled to the heat generating component 5 of the electronic unit 3. Each unit cooling system 6 can be attached to one or more heat generating components 5, here illustrated with two heat generating components. The housing 7 may be horizontal, or in other commonly used orientation, as long as the elevation of the condenser thermal interface coupling 16 is above that of the evaporator thermal interface coupling 15.

In an advantageous embodiment for the PHP, illustrated in FIGS. 2b, 4b and 6 to 6b, the fluid flow circuit comprises a multi-channel pipe 34 with end pieces 38 having therein a plurality of channels 36 forming a serpentine circuit for PHP cooling. The condenser end thermal interface coupling 16 of the multi-channel pipe 34 is clamped against a major surface 27 of the riser 8b. The unit cooling system 6 may comprise a second multi-channel pipe 34 having a thermal interface coupling 16 clamped to an opposing side 27 of the riser pipe, for instance as illustrated in FIG. 4b. The two multi-channel pipes 34 in FIG. 2b may be replaced by a single multi-channel pipe 34 for connecting two heat generating components 5 to the condenser end thermal interface coupling 16 to a major surface 27 of the riser 8b. Further fluid flow circuit pipes coupled to heat generating components in the electronic unit may be provided as part of the unit cooling system 6 in which case the condenser end thermal interface coupling 16 of both pipes may be clamped to the riser 8b just above or just below the condenser section of other fluid flow circuits of the unit cooling system 6. The housing 7 may be horizontal, or in other commonly used orientation.

The use of PHP or LTS cooling systems within each electronic unit 3 that are separate fluid circuits from the principal cooling system 4 of the stack (the stack cooling system 4) yet thermally coupled thereto along the riser 8b, provide a very flexible arrangement in which individual electronic units can be decoupled and coupled to the multi-unit electronic apparatus stack 1 and the associated stack cooling system 4 without interfering with the other electronic units. Moreover a fault in the cooling circuit of one of the unit cooling system 6 affects only a single electronic unit and thus the overall reliability and safety of the cooling system is improved.

The use of PHP and LTS cooling circuits in both the individual electronic units and the stack of electronic units provide a very compact cooling arrangement with a high power heat transfer per unit volume while yet a flexible, easy to install and reliable arrangement.

### LIST OF REFERENCES

Multi-unit electronic apparatus stack (e.g. server rack) 1
   Electronic unit (e.g. server) 3
      Electronic components 5
      Housing 7
Cooling system 2
   Stack cooling system 4
      Coolant
      Fluid flow circuit 8
         Downcomer 8a
         Riser 8b
         Riser pipe/tube 24
         Channels 39
         Internal separating walls (ribs) 41
         Outer wall 43
         Opposed major surfaces 27
   Unit thermal interface coupling 16
   Principal condenser 12
      Heat exchanger
         Liquid-liquid heat exchanger 26a
         Heat exchanger block 29
         Hot liquid circuit 30a
         Channels 25a
         Cool liquid circuit 30b
         Channels 25b
         Separating walls 35
         Outer walls 37
         Inlet 31a (from overhead air-liquid heat exchanger)
         Outlet 31b (to overhead air-liquid heat exchanger)
         (Overhead) Air-liquid heat exchanger 26b
         Fluid circuit
         Ventilator 32
         Overhead loop thermosyphon 33
Unit cooling system 6
   Coolant
   Fluid flow circuit 13
      LTS piping 14a, 14b
         Condenser line (pipe) 14a
         Evaporator line (pipe) 14b
      PHP piping/tube 34
         Channels 36
         Endpiece 38
   Condenser end (unit) thermal interface coupling 16
   Evaporator end thermal interface coupling 15

1. Cooling system for a multi-unit electronic apparatus stack comprising a plurality of stacked electronic units, the cooling system comprising a plurality of unit cooling systems incorporated in, on or between each electronic unit, each unit cooling system comprising one or more fluid flow circuits configured as:
a pulsating heat pipe (PHP) including a pipe having a plurality of channels therein arranged in a serpentine shape to form the pulsating heat pipe, the channels containing a coolant fluid, the pipe extending between a condenser end and an evaporator end,
the cooling system further comprising a stack cooling system comprising a principal condenser and a fluid flow circuit including a downcomer and a riser configured as a loop thermosyphon (LTS) cooling system, the riser comprising a riser pipe extending vertically across a plurality of stacked electronic units, each of the unit cooling systems comprising a thermal interface coupling clamped and thermally coupled to the riser pipe, the fluid flow circuits of the unit cooling systems being independent from the fluid flow circuit of the stack cooling system.

2. Cooling system according to the claim 1 wherein the riser pipe comprises a rectangular cross-section.

3. Cooling system according to claim 2 wherein the riser pipe cross-section has a length L to width W ratio L/W in a range of 30/1 to 3/1.

4. Cooling system according to claim 2 wherein the riser pipe has substantially flat opposed surfaces and the thermal interface coupling comprises a flat surface for clamping against the flat surface of the riser pipe.

5. Cooling system according to claim 1 wherein the riser pipe comprises a plurality of channels in which the coolant fluid circulates.

6. Cooling system according to claim 5 wherein the riser pipe comprises a single outer wall and internal walls integrally formed with the outer wall separating adjacent channels of said plurality of channels.

7. Cooling system according to claim 1 wherein the fluid flow circuit of the unit cooling system comprises an evaporator end having a major surface for thermally coupling against a heat generating electronic component of the electronic unit.

8. Cooling system according to claim 1 wherein the pipe of the unit cooling system is formed of an extruded metal piece, for instance an extruded aluminum piece.

9. Cooling system of claim 1 wherein the pulsating heat pipe (PHP) comprises end pieces forming caps assembled over and closing the condenser end and evaporator end of the pipe.

10. Cooling system according to claim 1 wherein pipe extends continuously between the condenser end and the evaporator end and comprises an intermediate twist bend configured to orient the condenser end in a vertical plane and the evaporator end in a horizontal plane.

11. Cooling system according to claim 1 wherein the downcomer of the stack cooling system comprises a single channel pipe.

12. Cooling system according to claim 1 wherein the principal condenser is arranged above a top of the multi-unit electronic apparatus stack.

13. Cooling system according to claim 1 wherein the principal condenser comprises an air-liquid heat exchanger.

14. Cooling system according to claim 1 wherein the principal condenser comprises a liquid-liquid heat exchanger including channels for flow of the coolant of the stack cooling system and channels separate therefrom for flow of a cooling liquid, for instance from an air-liquid heat exchanger, the channels including a plurality of alternating layers of said separate channels.

15. Cooling system according to claim 14 wherein the channels have a generally rectangular shape with a height H to width W ratio H/W in a range of 1.5 to 15, preferably in a range of 2 to 5.

16. Cooling system according to claim 14 wherein the liquid-liquid heat exchanger is a single integrally formed 3D printed part.

17. Cooling system according to claim 16 wherein the liquid-liquid heat exchanger is made of metal or plastic or polymer.

18. Cooling system according to claim 1 wherein the riser pipe comprises a constant continuous geometry extending across the plurality of electronic units configured to allow the clamping of thermal interface couplings of the unit cooling system at any position along the riser pipe.

19. Cooling system for a multi-unit electronic apparatus stack comprising a plurality of stacked electronic units, the cooling system comprising a plurality of unit cooling systems incorporated in, on or between each electronic unit, each unit cooling system comprising one or more fluid flow circuits configured as:
a pulsating heat pipe (PHP) including a pipe having one or more channels therein containing a coolant fluid, the pipe extending between a condenser end and an evaporator end, or
a thermosyphon (LTS) cooling system comprising pipes extending between a condenser end and an evaporator end;
the cooling system further comprising a stack cooling system comprising a principal condenser and a fluid flow circuit including a downcomer and a riser configured as a loop thermosyphon (LTS) cooling system, the riser comprising a riser pipe comprising a plurality of channels, the riser pipe having a substantially constant outer profile extending vertically across a plurality of stacked electronic units, each of the unit cooling systems comprising a thermal interface coupling configured to be releasably clamped and thermally coupled to the riser pipe, the fluid flow circuits of the unit cooling systems being independent from the fluid flow circuit of the stack cooling system.

20. Cooling system according to claim 19 wherein the riser pipe comprises a rectangular cross-section.

21. Cooling system according to claim 20 wherein the riser pipe cross-section has a length L to width W ratio L/W in a range of 30/1 to 3/1.

22. Cooling system according to claim 20 wherein the riser pipe has substantially flat opposed surfaces and the thermal interface coupling comprises a flat surface for clamping against the flat surface of the riser pipe.

23. Cooling system according to claim 19 wherein the unit cooling system is configured as a pulsating heat pipe (PHP), wherein the pipe of the PHP comprises a plurality of channels arranged in a serpentine shape.

24. Cooling system according to claim 23 wherein the pipe f the PHP is formed of an extruded metal piece, for instance an extruded aluminum piece.

25. Cooling system according to claim 19 wherein the fluid flow circuit of the unit cooling system comprises an evaporator end having a major surface for thermally coupling against a heat generating electronic component of the electronic unit.

26. Cooling system according to claim 19 wherein the downcomer of the stack cooling system comprises a single channel pipe.

27. Cooling system according to claim 19 wherein the principal condenser is arranged above a top of the multi-unit electronic apparatus stack.

28. Cooling system according to claim 19 wherein the principal condenser comprises an air-liquid heat exchanger.

29. Cooling system according to claim 19 wherein the principal condenser comprises a liquid-liquid heat exchanger including channels for flow of the coolant of the stack cooling system and channels separate therefrom for flow of a cooling liquid, for instance from a air-liquid heat exchanger, the channels including a plurality of alternating layers of said separate channels.

30. Cooling system according to claim 29 wherein the channels have a generally rectangular shape with a height H to width W ratio H/W in a range of 1.5 to 15, preferably in a range of 2 to 5.

31. Cooling system according to claim 29 wherein the liquid-liquid heat exchanger is a single integrally formed 3D printed part.

32. Cooling system according to claim 31 wherein the liquid-liquid heat exchanger is made of metal or plastic or a polymer.
